(19) United States
(12) Patent Application Publication
(10) Pub. No.: US 2024/0387443 A1
(43) Pub. Date: Nov. 21, 2024

(54) SEMICONDUCTOR MODULE AND METHOD FOR PRODUCING SEMICONDUCTOR MODULE

(71) Applicant: FUJI ELECTRIC CO., LTD., Kawasaki-shi (JP)

(72) Inventor: Daisuke INOUE, Matsumoto-city (JP)

(73) Assignee: FUJI ELECTRIC CO., LTD., Kawasaki-shi (JP)

(21) Appl. No.: 18/605,734

(22) Filed: Mar. 14, 2024

(30) Foreign Application Priority Data
May 19, 2023 (JP) 2023-082833

(51) Int. Cl. H01L 23/00; H01L 21/48; H01L 23/31; H01L 25/07; H01L 25/18

(52) U.S. Cl. CPC H01L 24/48; H01L 21/4825; H01L 23/31; H01L 24/85; H01L 25/072; H01L 25/18; H01L 2224/48247; H01L 2224/48465; H01L 2224/85205; H01L 2924/13055

(57) ABSTRACT

A semiconductor module includes: a circuit board including a semiconductor element; a housing for housing the semiconductor element; a lead terminal penetrating the housing; and a bonding wire electrically connecting the semiconductor element to the lead terminal within the housing, in which the lead terminal includes a pad coupled to the bonding wire, the housing includes a recess having a bottom surface constituted of at least a part of the pad such that the recess surrounds the pad, a first side surface of the recess overlaps with the bonding wire as viewed in a thickness direction of the circuit board, the first side surface has a first end adjacent to the bottom surface and a second end close to the semiconductor element, the first side surface is inclined relative to a direction perpendicular to the pad such that the second end is higher than the first end.

### CROSS REFERENCE TO RELATED APPLICATION

This Application is based on, and claims priority from, Japanese Patent Application No. 2023-082833, filed on May 19, 2023, the entire contents of which are incorporated herein by reference.

### BACKGROUND

### Technical Field

The present disclosure relates to a semiconductor module and to a method for producing a semiconductor module.

### Related Art

A semiconductor module such as a power semiconductor module generally includes a circuit board provided with a semiconductor element, a housing for housing the semiconductor element, and a plurality of lead terminals electrically connected to the circuit board. Each of the plurality of lead terminals penetrates the housing to extend from the inside of the housing to the outside of the housing, and each of the plurality of lead terminals is electrically connected to the semiconductor element via a bonding wire, as disclosed in Japanese Patent Application Laid-Open Publication No. 2021-184449, WO 2015/152373, Japanese Patent Application Laid-Open Publication No. 2017-199818, and Japanese Patent Application Laid-Open Publication No. 2022-82033, for example.

In a state in which ultrasonic waves are used for wire bonding by which a bonding wire is coupled to a lead terminal, coupling strength of the lead terminal to the housing may be reduced by resonance. To overcome the disadvantage, as disclosed in Japanese Patent Application Laid-Open Publication No. 2021-184449 and WO 2015/152373, a configuration may be conceived in which a housing is provided with a recess having a bottom surface that is constituted of a pad of the lead terminal so as to press the pad against the housing, the pad being used for wire bonding. However, in the configuration disclosed in Japanese Patent Application Laid-Open Publication No. 2021-184449 and WO 2015/152373, the recess has a closed side surface, and the entirety of the closed side surface of the recess is steeply inclined relative to the pad. Thus, the configuration may cause a decrease in reliability when a bonding wire comes into contact with the housing.

### SUMMARY

In view of the circumstances described above, an object of one aspect according to the present disclosure is to provide a semiconductor module having high reliability.

To solve the above problem, a semiconductor module according to an aspect of the present disclosure includes: a circuit board provided with a semiconductor element; a housing for housing the semiconductor element; a lead terminal penetrating the housing to extend from an inside of the housing to an outside of the housing; and a bonding wire for electrically connecting the semiconductor element and the lead terminal to each other within the housing, in which the lead terminal includes a pad coupled to the bonding wire, in which the housing includes a recess having a bottom surface that is constituted of at least a part of the pad such that the recess surrounds the pad, in which the recess has a side surface including a first side surface, in which the first side surface overlaps with the bonding wire as viewed in a direction of thickness of the circuit board, in which the first side surface has a first end adjacent to the bottom surface and a second end closer to the semiconductor element than the first end, and in which the first side surface is inclined relative to a direction perpendicular to the pad such that the second end of the first side surface is higher than the first end of the first side surface.

A method for producing a semiconductor module according to another aspect of the present disclosure is a method for producing a semiconductor module, the semiconductor module including: a circuit board provided with a semiconductor element; a housing for housing the semiconductor element; a lead terminal penetrating the housing to extend from an inside of the housing to an outside of the housing; and a bonding wire for electrically connecting the semiconductor element and the lead terminal to each other within the housing, the method including: preparing a lead frame including the lead terminal; forming the housing by insert molding in which a mold is used and the lead frame is used as an insert; and forming the bonding wire, in which the lead terminal includes a pad coupled to the bonding wire, in which the housing includes a recess having a bottom surface that is constituted of at least a part of the pad such that the recess surrounds the pad, in which the recess has a side surface including a first side surface, in which the first side surface overlaps with the bonding wire as viewed in a direction of thickness of the circuit board, in which the first side surface has a first end adjacent to the bottom surface and a second end closer to the semiconductor element than the first end, and in which the first side surface is inclined relative to a direction perpendicular to the pad such that the second end of the first side surface is higher than the first end of the first side surface.

According to one aspect of the present disclosure, it is possible to improve reliability of a semiconductor module.

### BRIEF DESCRIPTION OF THE DRAWINGS

FIG. 1 is a plan view of a semiconductor module according to a first embodiment.

FIG. 2 is a cross section taken along line A-A in FIG. 1.

FIG. 3 is a perspective view of the semiconductor module in which a plurality of pads included in a plurality of lead terminals is electrically connected to a circuit board.

FIG. 4 is a plan view of a pad of a lead terminal and a recess of a housing.

FIG. 5 is a cross section taken along line B-B in FIG. 4.

FIG. 6 is a diagram showing a method for producing the semiconductor module according to the first embodiment.

FIG. 7 is a diagram explaining a preparation step.

FIG. 8 is a diagram explaining a housing formation step.

FIG. 9 is a diagram explaining a wire formation step and a coating step.

### DESCRIPTION OF EMBODIMENTS

Embodiments according to the present disclosure will be described with reference to the drawings. In the drawings, dimensions and scales of elements may differ from those of actual products, and some elements may be shown schematically to facilitate understanding. The scope of the present disclosure is not limited to the embodiments described below unless the following explanation includes a description that specifically limits the scope of the present disclosure.

### 1. First Embodiment

### 1-1. Overall Configuration of Semiconductor Module

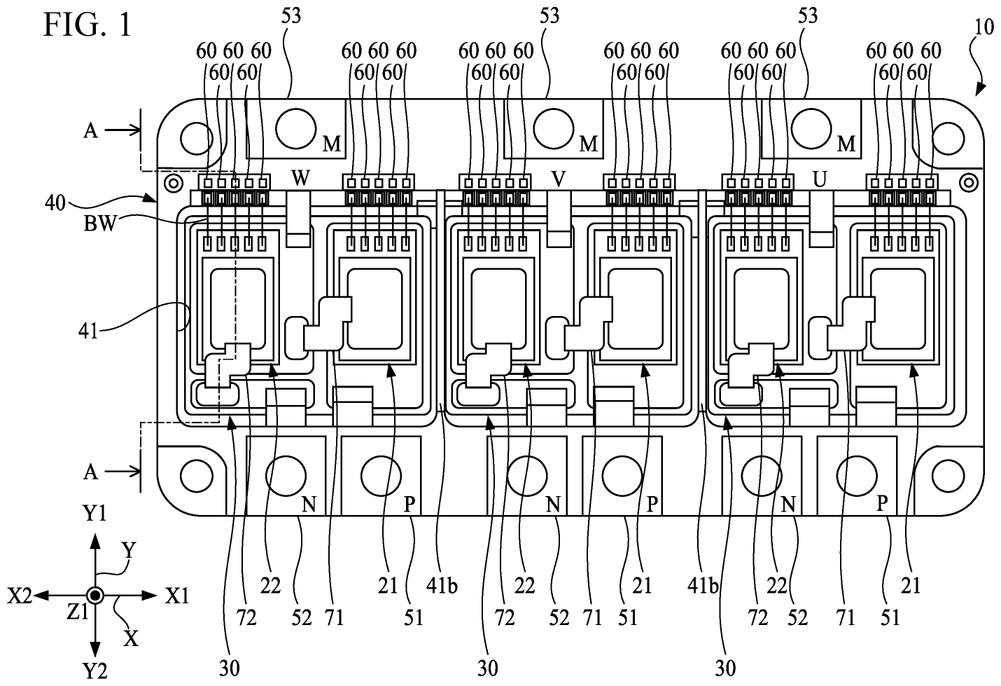

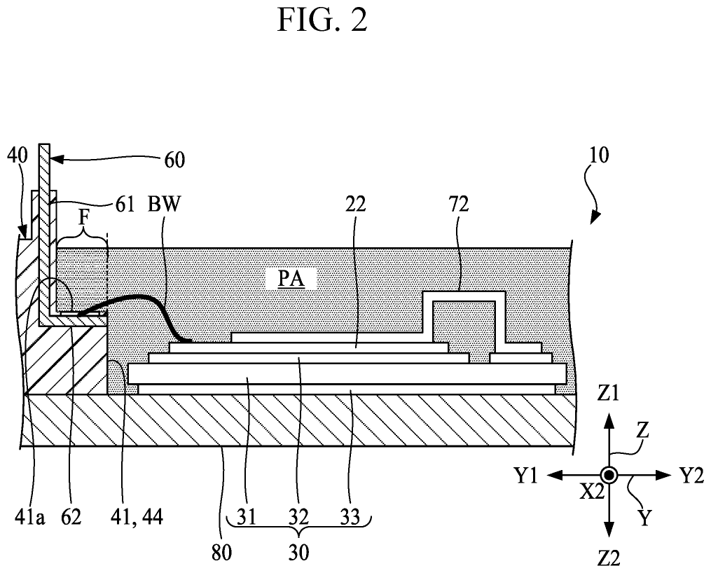

FIG. 1 is a plan view of a semiconductor module 10 according to a first embodiment. FIG. 2 is a cross section taken along line A-A in FIG. 1. The semiconductor module 10 is a power module such as an insulated gate bipolar transistor (IGBT) module. The semiconductor module 10 is used, for example, to power control a device such as an inverter or a rectifier. The inverter or the rectifier may be disposed on an apparatus such as an industrial machine, a railway vehicle, an automobile, or a household electrical machine.

As shown in FIG. 1 and FIG. 2, the semiconductor module 10 includes a plurality of semiconductor elements 21 and 22, a plurality of circuit boards 30, a housing 40, a plurality of terminals 51, 52, and 53, a plurality of lead terminals 60, a plurality of wiring boards 71 and 72, a base 80, a plurality of bonding wires BW, and an encapsulating resin material PA. In FIG. 1, the encapsulating resin material PA is omitted for convenience.

First, an outline of each element of the semiconductor module 10 will be described with reference to FIG. 1 and FIG. 2. For convenience, in the following description, an X-axis, a Y-axis, and a Z-axis are defined that are perpendicular to one another. The Z-axis is an axis parallel to a direction of thickness of the semiconductor module 10. In the following description, a direction along the X-axis is referred to as a direction X1, and a direction opposite to the direction X1 is referred to as a direction X2. A direction along the Y-axis is referred to as a direction Y1, and a direction opposite to the direction Y1 is referred to as a direction Y2. A direction along the Z-axis is referred to as a direction Z1, and a direction opposite to the direction Z1 is referred to as a direction Z2. The relationship between each of these directions and the vertical direction is not particularly limited, and the relationship may be freely selected. In the following description, a view in a direction along the Z-axis may be referred to as a “plan view.”

The semiconductor elements 21 and 22 are each a switching element such as an insulated gate bipolar transistor (IGBT) or a power metal oxide semiconductor field effect transistor (MOSFET). The semiconductor elements 21 and 22 each have a rear surface provided with an input electrode, which is a drain electrode or a collector electrode. The semiconductor elements 21 and 22 each have a front surface provided with an output electrode, which is a source electrode or an emitter electrode, and a control electrode, which is a gate electrode.

In this embodiment, the semiconductor elements 21 and 22 are each an element such as a reverse conducting insulated gate bipolar transistor (RC-IGBT) that includes both a function of an insulated gate bipolar transistor (IGBT) and a function of a freewheeling diode (FWD). In other words, the semiconductor elements 21 and 22 each include not only the switching element, but also a diode such as a FWD. Thus, the rear surface of each of the semiconductor elements 21 and 22 is provided with not only the input electrode, but also a cathode electrode. The front surface of each of the semiconductor elements 21 and 22 is provided with not only the output electrode, but also an anode electrode.

In an example shown in FIG. 1, the number of semiconductor elements 21 is three, and the number of semiconductor elements 22 is three, and the semiconductor elements 21 are paired with the semiconductor elements 22, individually. In other words, three pairs of semiconductor elements 21 and 22 exist. The three pairs of semiconductor elements 21 and 22 constitute three half-bridge circuits that have a half-bridge circuit for a U-phase, a half-bridge circuit for a V-phase, and a half-bridge circuit for a W-phase. The semiconductor elements 21 are each a high potential side element, whereas the semiconductor elements 22 are each a low potential side element.

The number of pairs of semiconductor elements 21 and 22 is not limited to the example shown in FIG. 1. The number of pairs of semiconductor elements 21 and 22 may be freely selected. The diode such as a FWD may be separate from each of the semiconductor elements 21 and 22.

The plurality of semiconductor elements 21 and the plurality of semiconductor elements 22 are disposed on the plurality of circuit boards 30.

Each circuit board 30 of the plurality of circuit boards 30 is a circuit board 30 that is a laminated substrate such as a direct copper bonding (DCB) substrate or an active metal brazing (AMB) substrate. The circuit board 30 includes an insulated substrate 31 having a front surface and a rear surface, a circuit plate 32 provided on the front surface of the insulated substrate 31, and a heat radiating plate 33 provided on the rear surface of the insulated substrate 31.

The insulated substrate 31 is made of, for example, a ceramic material such as an aluminum nitride material, an aluminum oxide material, or a silicon nitride material. The circuit plate 32 and the heat radiating plate 33 are each made of, for example, a metallic material such as a copper material or an aluminum material. The circuit plate 32 constitutes a part of a path for a main current for the semiconductor module 10. The heat radiating plate 33 has a function of radiating heat conducted from the semiconductor elements 21 and 22.

In the example shown in FIG. 1, the number of circuit boards 30 is three, and three circuit boards 30 correspond to the three pairs of semiconductor elements 21 and 22. The circuit plate 32 of each of the three circuit boards 30 is constituted of three island-shaped portions that are spaced apart from one another. A first portion among the three island-shaped portions of the circuit plate 32 is coupled by a conductive bonding material such as a solder material to a rear surface of a corresponding semiconductor element 21 and to a corresponding terminal 51. A second portion, which is different from the first portion, among the three island-shaped portions of the circuit plate 32 is coupled by a conductive bonding material such as a solder material to a rear surface of a corresponding semiconductor element 22 and to one end of a corresponding wiring board 71. The other end of the corresponding wiring board 71 is coupled by a conductive bonding material such as a solder material to a front surface of the corresponding semiconductor element 21. A third portion, which is different from both the first portion and the second portion, among the three island-shaped portions of the circuit plate 32, is coupled by a conductive bonding material such as a solder material to a corresponding terminal 52 and to one end of a corresponding wiring board 72. The other end of the corresponding wiring board 72 is coupled by a conductive bonding material such as a solder material to a front surface of the corresponding semiconductor element 22. The solder material may be a lead-free solder material. The lead-free solder material may be mainly made of an alloy containing at least two of tin, silver, copper, zinc, antimony, indium, and bismuth. The solder material may include one or more additives. An additive may be a nickel material, a germanium material, a cobalt material, or a silicon material. The shape of the circuit plate 32 shown in FIG. 1 is an example. The shape of the circuit plate 32 is not limited thereto.

The wiring boards 71 and 72 are each a conductive member. The wiring boards 71 and 72 may each be made of a metallic material such as a copper material, a copper alloy, an aluminum material, an aluminum alloy, or an iron alloy. The wiring boards 71 and 72 may each be formed by bending a metallic plate. The shape of the wiring board 71 is not limited to the example shown in FIG. 1. The shape of the wiring board 71 may be freely selected.

The housing 40 is a frame-shaped member that houses the plurality of semiconductor elements 21 and the plurality of semiconductor elements 22 that are disposed on the plurality of circuit boards 30. The housing 40 is a substantial insulator. The housing 40 may be made of a resin composition containing a resin material such as an epoxy resin material, a polyphenylene sulfide (PPS) material, a polybutylene terephthalate (PBT) material. The resin composition may include an inorganic filler such as an alumina material or a silica material so as to improve mechanical strength or thermal conductivity of the housing 40. The housing 40 made of the resin composition is formed by insert molding in which the plurality of terminals 51, 52, and 53 and the plurality of lead terminals 60 are used as inserts. Thus, the housing 40 is integrally formed together with the plurality of terminals 51, 52, and 53 and the plurality of lead terminals 60. The resin material of the resin composition is not limited to a thermoplastic resin material. The resin material of the resin composition may be a thermosetting resin material.

As described below, the housing 40 has an inner wall surface F to which a coating material CA is applied. The inner wall surface F of the housing 40 is adjacent to the plurality of circuit boards 30. The coating material CA enhances adhesion of the housing 40 to the encapsulating resin material PA. Thus, since the adhesion of the housing 40 to the encapsulating resin material PA is improved, it is possible to improve reliability of the semiconductor module 10.

In the example shown in FIG. 1, the housing 40 has an opening 41 that surrounds, in plan view, the plurality of semiconductor elements 21 and 22 disposed on the three circuit boards 30. The opening 41 is divided in three spaces with two partitions 41b. In each of the three spaces, a corresponding circuit board 30 among the three circuit boards 30 is disposed. The housing 40 has a wall surface defining the opening 41. The wall surface defining the opening 41 is provided with a step surface 41a facing in the direction Z1. The step surface 41a is provided with a pad 62 that is included in each of the plurality of lead terminals 60. The pad 62 will be described below. The shape of the opening 41 is not limited to the example shown in FIG. 1 and FIG. 2. For example, the partitions 41b may be omitted.

Since the housing 40 is integrally formed together with the plurality of terminals 51, 52, and 53 and the plurality of lead terminals 60, the housing 40 is provided with the plurality of terminals 51, 52, and 53 and the plurality of lead terminals 60.

The plurality of terminals 51, 52, and 53 are each a terminal for connecting the semiconductor module 10 and a bus bar (not shown) to each other. The plurality of terminals 51, 52, and 53 may each be made of a metallic material such as a copper material, a copper alloy, an aluminum material, an aluminum alloy, or an iron alloy. The plurality of terminals 51, 52, and 53 may each be formed by bending a metallic plate.

In the example shown in FIG. 1, the terminals 51, 52, and 53 are used for the U-phase, the V-phase, and the W-phase, respectively. The number of terminals 51 is three, the number of terminals 52 is three, and the number of terminals 53 is three. The terminals 51 are each a terminal for a high potential side. The terminals 51 are each electrically connected to the rear surface of a corresponding semiconductor element 21 via the first portion of the circuit plate 32 of a corresponding circuit board 30. The terminals 52 are each a terminal for a low potential side. The terminals 52 are each electrically connected to a front surface of a corresponding semiconductor element 22 via the third portion of the circuit plate 32 of a corresponding circuit board 30 and a corresponding wiring board 72. The terminals 53 are each an output terminal. The terminals 53 are each electrically connected to the rear surface of a corresponding semiconductor element 22 via the second portion of the circuit plate 32 of a corresponding circuit board 30.

Each lead terminal 60 of the plurality of lead terminals 60 is a lead terminal 60 for connecting the semiconductor module 10 to a control circuit (not shown) for controlling operation of the semiconductor elements 21 and 22. The lead terminal 60 penetrates the housing 40 to extend from the inside of the housing 40 to the outside of the housing 40. The control circuit is disposed outside the semiconductor module 10. The control circuit provides the lead terminal 60 with a signal for controlling operation of the semiconductor elements 21 and 22. The lead terminal 60 as well as the plurality of terminals 51, 52, and 53 may be made of a metallic material such as a copper material, a copper alloy, an aluminum material, an aluminum alloy, or an iron alloy. The lead terminal 60 may be formed by bending a metallic plate.

In the example shown in FIG. 1, the plurality of lead terminals 60 includes ten lead terminals 60 for each of the phases including the U-phase, V-phase, and the W-phase. Five lead terminals 60 among the ten lead terminals 60 correspond to a semiconductor element 21, and the other five lead terminals 60 correspond to a semiconductor element 22. The number of lead terminals 60 is not limited to the example shown in FIG. 1. The number of lead terminals 60 may be changed as appropriate. The position of each of the lead terminals 60 is not limited to the example shown in FIG. 1. The position of each of the lead terminals 60 may be changed as appropriate.

As shown in FIG. 2, the lead terminal 60 is made of a metallic plate having an L-shape. The lead terminal 60 has a pin 61 and the pad 62.

The pin 61 is a bar-shaped portion of the lead terminal 60. The pin 61 extends in the direction along the Z-axis. The pin 61 has an end in the direction Z1. The end of the pin 61 in the direction Z1 protrudes from an outer wall surface of the housing 40. Thus, the pin 61 includes a terminal portion that protrudes from the outer wall surface of the housing 40. The terminal portion of the pin 61 is connected to a substrate (not shown) provided with the semiconductor module 10. The pin 61 has the other end in the direction Z2. The end of the pin 61 in the direction Z2 is continuous with the pad 62. The shape of the pin 61 is not limited to the example shown in FIG. 1. The shape of the pin 61 may be such that the tip of the pin 61 branches into two parts, for example.

The pad 62 is a plate-shaped portion of the lead terminal 60. The pad 62 is disposed along the step surface 41a of the housing 40. The pad 62 extends from the end of the pin 61 in the direction Z2 toward the inside of the housing 40. The pad 62 includes a portion exposed in a space within the housing 40. The exposed portion of the pad 62 is coupled to one end of a bonding wire BW among the plurality of bonding wires BW. The other end of the bonding wire BW is connected to a control electrode (not shown) of a corresponding semiconductor element 21 or 22.

Thus, the bonding wire BW electrically connects a corresponding circuit board 30 and the lead terminal 60 to each other within the housing 40. The bonding wire BW may be made of a metallic material such as a copper material, a copper alloy, an aluminum material, or an aluminum alloy. The number of bonding wires BW is not limited to the example shown in FIG. 1. For example, two or more bonding wires BW may be used for a pad 62.

The base 80 is a plate-shaped member for radiating heat. The base 80 constitutes a bottom plate of the semiconductor module 10. The base 80 has an upper surface coupled by a bonding material such as a solder material to the plurality of circuit boards 30. In addition, the upper surface of the base 80 is bonded by an adhesive such as an epoxy-based adhesive or a silicone-based adhesive to one end of the housing 40 in the direction Z2. The base 80 has a lower surface that may be provided with a heat radiating member or a cooler such as a heat radiating fin (not shown). The base 80 is a metallic plate made of a copper material, a copper alloy, an aluminum material, or an aluminum alloy, for example. The base 80 is thermally conductive. The base 80 radiates heat conducted from the plurality of semiconductor elements 21 and 22. In addition, the base 80 has electrical conductivity. The base 80 may be electrically connected to a reference potential line such as a ground potential line. The base 80 may be integrally formed together with a heat radiating member or a cooling member such as a heat radiating fin.

The encapsulating resin material PA is a potting material with which the housing 40 is filled. The encapsulating resin material PA includes a thermosetting resin material such as an epoxy resin material or a silicone resin material. The encapsulating resin material PA may include an inorganic filler such as a silica material or an alumina material so as to improve thermal conductivity thereof. The encapsulating resin material PA may be gelatinous.

### 1-2. Configuration of Housing in Vicinity of Pad of Lead Terminal

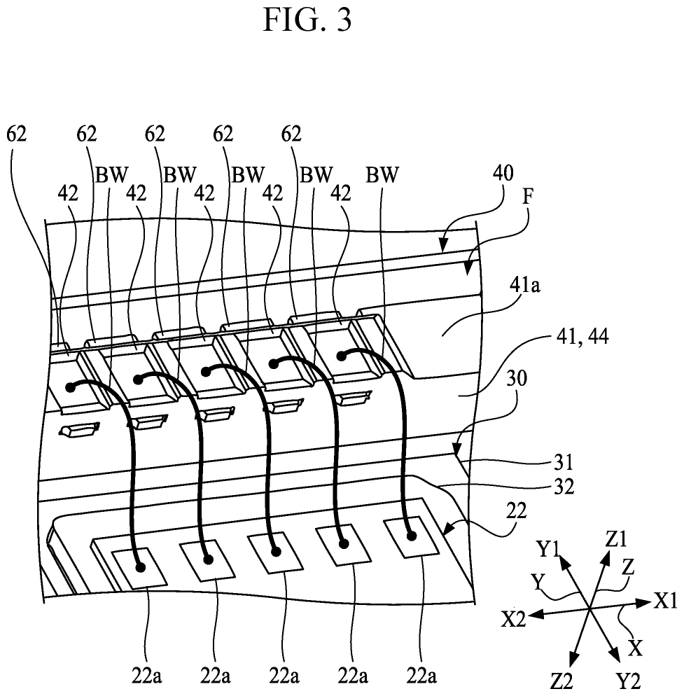

FIG. 3 is a perspective view of the semiconductor module 10 in which a plurality of pads 62 included in a plurality of lead terminals 60 is electrically connected to a circuit board 30. In FIG. 3, five pads 62 corresponding to a semiconductor element 22 and five bonding wires BW corresponding to the semiconductor element 22 are shown. The semiconductor element 22 includes five control electrodes 22a corresponding to the five pads 62. The five control electrodes 22a are each a control electrode 22a electrically connected to a corresponding pad 62 via a corresponding bonding wire BW.

In an example shown in FIG. 3, a pad 62 and a control electrode 22a corresponding the pad 62 are aligned with each other in a direction along the Y-axis as viewed in the direction along the Z-axis. Thus, each of the bonding wires BW extends in the direction along the Y-axis as viewed in the direction along the Z-axis. In other words, the pads 62 are aligned with each other along a long side of the housing 40, and the control electrodes 22a are aligned with each other along the long side of the housing 40, and the bonding wires BW are aligned with each other along the long side of the housing 40. The direction of extension of each of the bonding wires BW is determined depending on a positional relationship between the corresponding pad 62 and the corresponding control electrode 22a. The direction of extension of each of the bonding wires BW is not limited to the example shown in FIG. 3. For example, the direction of extension of each of the bonding wires BW may be a direction inclined relative to the Y-axis as viewed in the direction along the Z-axis.

As shown in FIG. 3, the housing 40 includes a plurality of recesses 42. Each recess 42 of the plurality of recesses 42 is a recess 42 that surrounds a corresponding pad 62. In other words, the recess 42 has a bottom surface that is constituted of at least a part of the pad 62 such that the recess 42 surrounds the at least the part of the pad 62. The pad 62 has a surface facing in the direction Z1. The bottom surface of the recess 42 is at least a part of the surface of the pad 62 facing in the direction Z1. The bottom surface of the recess 42 is exposed in the space within the recess 42. In other words, the bottom surface of the recess 42 is at least a part of the surface of the pad 62 opposite to a surface of the pad 62 facing in a direction of the base 80, the bottom surface of the recess 42 being exposed in the space within the recess 42. In the recess 42, a direction of depth of the recess 42 is the direction along the Z-axis. In the example shown in FIG. 3, the step surface 41a of the housing 40 is provided with the recess 42.

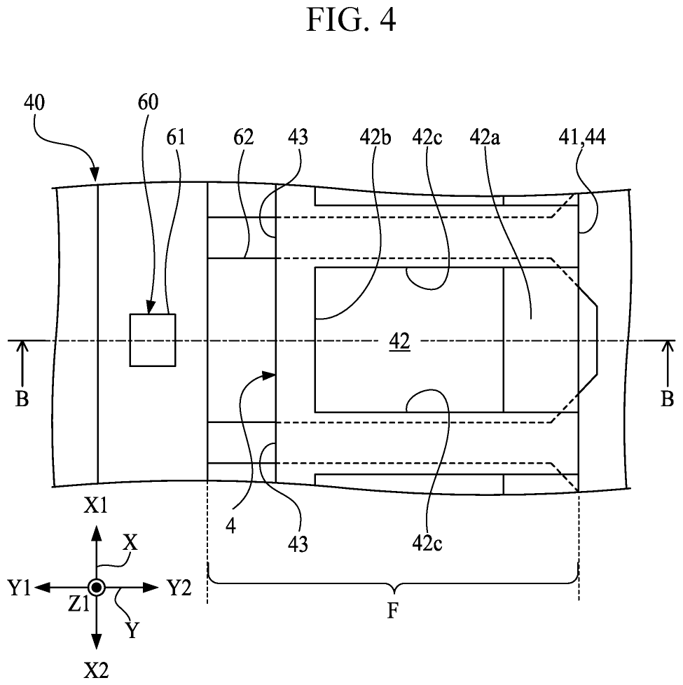

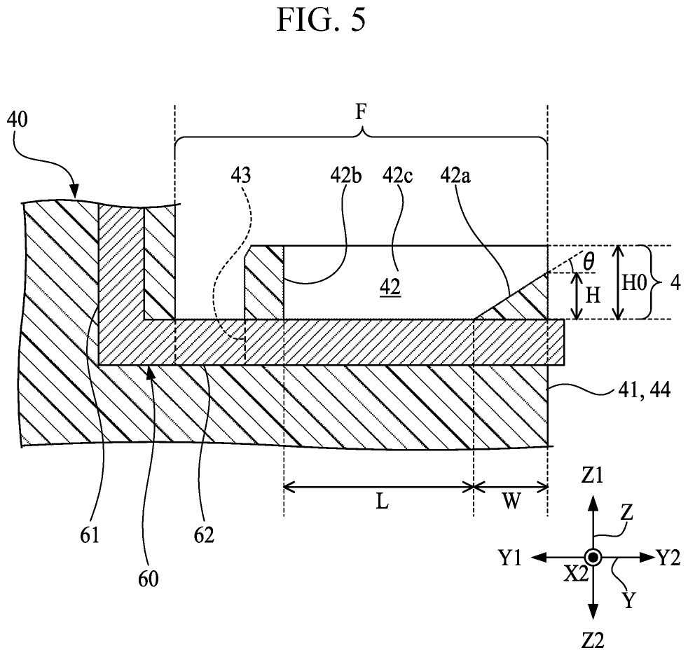

FIG. 4 is a plan view of the pad 62 of the lead terminal 60 and the recess 42 of the housing 40. FIG. 5 is a cross section taken along line B-B in FIG. 4. In FIG. 4 and FIG. 5, the bonding wire BW is omitted for convenience.

As shown in FIG. 4 and FIG. 5, the housing 40 has a wall 4 that defines a side surface of the recess 42. The wall 4 is included in the housing 40. As shown in FIG. 4, the wall 4 overlaps with at least a part of an outer peripheral edge of the pad 62 as viewed in the direction along the Z-axis. As shown in FIG. 5, the wall 4 is disposed in the direction Z1 from the pad 62. In other words, the wall 4 overlaps with at least the part of the outer peripheral edge of the pad 62 in plan view, and the wall 4 is closer to the outer wall surface of the housing 40 than the pad 62, the pin 61 protruding from the outer wall surface of the housing 40. Thus, it is possible to connect the bonding wire BW to the pad 62, and the wall 4 can press the pad 62 against the housing 40.

As described above, the housing 40 includes the recess 42 having the bottom surface that is constituted of at least the part of the pad 62 such that the recess 42 surrounds the pad 62. Thus, the pad 62 is pressed against the housing 40. As a result, in a state in which ultrasonic waves are used for wire bonding by which the bonding wire BW is coupled to the lead terminal 60, it is possible to substantially prevent resonance from causing a decrease in coupling strength of the lead terminal 60 to the housing 40. In addition, since the housing 40 is provided with the recess 42, it is possible to maintain the coating material CA, which enhances adhesion of the housing 40 to the encapsulating resin material PA, in the recess 42. As a result, adhesion of the housing 40 to the encapsulating resin material PA can be improved by the coating material CA.

As shown in FIG. 4, the bottom surface of the recess 42 has a shape of a rectangle that has a pair of sides along the X-axis and a pair of sides along the Y-axis, as viewed in the direction along the Z-axis. In other words, in plan view, the bottom surface of the recess 42 has a shape of a rectangle that has a pair of sides along the long side of the housing 40 and a pair of sides along a short side of the housing 40. The side surface of the recess 42 has a first side surface 42a along the X-axis, a second side surface 42b along the X-axis, and a pair of second side surfaces 42c along the Y-axis.

The first side surface 42a of the side surface of the recess 42 overlaps with a corresponding bonding wire BW as viewed in a direction of thickness of a corresponding circuit board 30 among the plurality of circuit boards 30. The second side surfaces 42b and 42c of the side surface of the recess 42 are each different from the first side surface 42a. The first side surface 42a is spaced apart from the second side surface 42b in the direction Y2. In other words, the first side surface 42a is closer to the circuit board 30 than the second side surface 42b. One of the pair of second side surfaces 42c has one end in the direction Y2 and the other end in the direction Y1, the one end in the direction Y2 being continuous with one end of the first side surface 42a in the direction X1, the other end in the direction Y1 being continuous with one end of the second side surface 42b in the direction X1. The other of the pair of second side surfaces 42c has one end in the direction Y2 and the other end in the direction Y1, the one end in the direction Y2 being continuous with the other end of the first side surface 42a in the direction X2, the other end in the direction Y1 being continuous with the other end of the second side surface 42b in the direction X2.

The first side surface 42a has a first end adjacent to the bottom surface of the recess 42 and a second end closer to a corresponding semiconductor element 21 or 22 than the first end. The first side surface 42a is inclined at an inclination angle θ relative to a direction perpendicular to the pad 62 such that the second end of the first side surface 42a is higher than the first end of the first side surface 42a. Thus, when the bonding wire BW is coupled to the pad 62 and the control electrode 22a, it is possible to reduce contact between the first side surface 42a of the housing 40 and a wire coupling tool (not shown) for coupling the bonding wire BW, and it is possible to reduce contact between the bonding wire BW and the housing 40. In addition, as described above, since the housing 40 is provided with the recess 42, it is possible to substantially prevent a decrease in coupling strength of the lead terminal 60 to the housing 40. In addition, the coating material CA can enhance adhesion of the housing 40 to the encapsulating resin material PA. As a result, it is possible to improve reliability of the semiconductor module 10.

In an example shown in FIG. 5, the first side surface 42a is a plane. The shape of the first side surface 42a is not limited to the example shown in FIG. 5. The first side surface 42a may have a convex curved shape, a concave curved shape, or a stepped shape. The first side surface 42a may have a plurality of portions that have different inclination angles relative to the pad 62.

A height H of the first side surface 42a in a direction of depth of the recess 42 is less than a height HO of each of the second side surfaces 42b and 42c in the direction of depth of the recess 42. Compared to a configuration in which the height H of the first side surface 42a is greater than or equal to the height HO of each of the second side surfaces 42b and 42c, a configuration in which the height H of the first side surface 42a is less than the height HO of each of the second side surfaces 42b and 42c can reduce contact between the bonding wire BW and the housing 40. In addition, since the height HO of each of the second side surfaces 42b and 42c is greater than the height H of the first side surface 42a, it is possible to maintain the coating material CA in the recess 42.

The direction of depth of the recess 42 is the direction Z1 or the direction Z2. The height H may be greater than or equal to the height HO. However, to maintain the coating material CA in the recess 42, the height H is preferably less than the height HO.

As shown in FIG. 4, the housing 40 includes two recess-shaped notches 43. The two recess-shaped notches 43 are each a recess that is recessed in the direction Z2 from the surface of the pad 62 facing in the direction Z1. In other words, the two recess-shaped notches 43 are each a recess that is recessed in a direction from a rear surface of the pad 62 toward the base 80. The lead terminal 60 having the pad 62 includes a portion adjoining the recess 42. The two recess-shaped notches 43 are formed such that the portion of the lead terminal 60 adjoining the recess 42 is sandwiched between the two recess-shaped notches 43. In an example shown in FIG. 4, the pad 62 is sandwiched between the two recess-shaped notches 43 at the outside of the wall 4 as viewed in the direction along the Z-axis. As described above, the two recess-shaped notches 43 are formed such that the portion of the lead terminal 60 adjoining the recess 42 is sandwiched between the two recess-shaped notches 43. In addition, as described below, a lower mold 110 of a mold 100 for molding of the housing 40 is provided with a plurality of protrusion-shaped regulators 112 corresponding to the 20) two recess-shaped notches 43. Thus, it is possible to reduce misalignment of the lead terminal 60 during formation of the housing 40. In addition, the encapsulating resin material PA enters the two recess-shaped notches 43. Thus, adhesion area between the housing 40 and the encapsulating resin material PA is increased, and it is possible to enhance adhesion of the housing 40 to the encapsulating resin material PA.

In the example shown in FIG. 4, the part of the pad 62 inside the recess 42 is exposed in the housing 40, and a tip of the pad 62 is exposed in the housing 40. The tip of the pad 62 as well as the regulators 112 described below can be used for positioning of the lead terminal 60 relative to the mold 100.

As described above, the housing 40 has a shape of a frame. H/W is preferably in a range of 0.5 or more and 2.0 or less, in which W is a distance between the first end of the first side surface 42a and an inner peripheral surface 44 (inner peripheral edge) of the housing 40, and H is the height of the first side surface 42a. In a state in which H/W is in the range, it is possible to shorten a distance between the pad 62 and the circuit board 30, and it is possible to implement the first side surface 42a having the inclination angle θ at which contact between the bonding wire BW and the housing 40 tends to be reduced. The distance W may be referred to as the width of the first side surface 42a of the wall 4 in the direction along the Y-axis.

H/L is preferably in a range of 0.2 or more and 0.8 or less, in which L is the length of the bottom surface of the recess 42 in the direction of expansion of the bonding wire BW as viewed in the direction of thickness of the circuit board 30, and H is the height of the first side surface 42a. In a state in which H/L is in the range, it is possible to reduce a size of the pad 62, and it is possible to implement the first side surface 42a having a height at which contact between the bonding wire BW and the housing 40 tends to be reduced.

The inclination angle θ of the first side surface 42a relative to the pad 62 is preferably 45° or less. In a state in which the inclination angle θ is in this range, it is possible to reduce contact between the bonding wire BW and the housing 40 compared to a configuration in which the inclination angle θ of the first side surface 42a relative to the pad 62 is greater than 45°. The inclination angle θ is an angle between the first side surface 42a and the surface of the pad 62 facing in the direction Z1.

In the example shown in FIG. 4 and FIG. 5, the second side surfaces 42b and 42c are each perpendicular to the surface of the pad 62 facing in the direction Z1. Thus, an angle between the surface of the pad 62 facing in the direction Z1 and each of the second side surfaces 42b and 42c is greater than the inclination angle θ. As a result, an advantage is obtained in that the coating material CA maintains in the recess 42. The second side surfaces 42b and 42c may each be inclined relative to the surface of the pad 62 facing in the direction Z1, instead of being perpendicular to the surface of the pad 62 facing in the direction Z1. In this case, the angle between the surface of the pad 62 facing in the direction Z1 and each of the second side surfaces 42b and 42c may be equal to or different from the inclination angle θ. Thus, the coating material CA readily flows into the recess 42.

### 1-3. Method for Producing Semiconductor Module

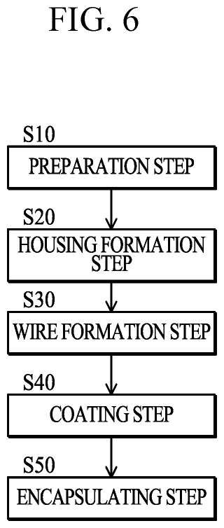

FIG. 6 is a diagram showing a method for producing the semiconductor module 10 according to the first embodiment. As shown in FIG. 6, the method for producing the semiconductor module 10 includes a preparation step S10, a housing formation step S20, a wire formation step S30, a coating step S40, and an encapsulating step S50 in this sequence.

At the preparation step S10, elements are prepared that are required for the housing formation step S20. The elements include a lead frame 600 that includes the plurality of lead terminals 60. The lead frame 600 will be described below. At the housing formation step S20, the housing 40 is formed by insert molding in which the mold 100 is used and the lead frame 600 is used as an insert. At the wire formation step S30, the plurality of bonding wires BW is formed. At the coating step S40, coating is performed for enhancing adhesion of the housing 40 to the encapsulating resin material PA. At the encapsulating step S50, the encapsulating resin material PA is formed. Each step will be described in order.

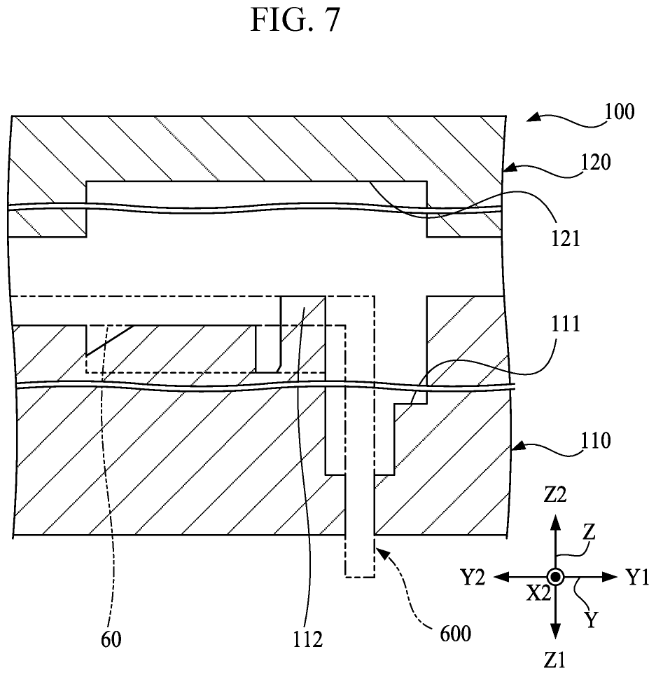

FIG. 7 is a diagram explaining the preparation step S10. As shown in FIG. 7, at the preparation step S10, the mold 100 and the lead frame 600 including the plurality of lead terminals 60 are prepared. In addition, at the preparation step S10, not only the mold 100 and the lead frame 600, but also elements required for the housing formation step S20 are prepared as appropriate.

The lead frame 600 includes the plurality of lead terminals 60 and the other portions. The other portions of the lead frame 600 are cut after the housing formation step S20.

The mold 100 has the lower mold 110 and an upper mold 120. The lower mold 110 includes a molding surface 111 for forming a front surface of the housing 40. The molding surface 111 is provided with the plurality of regulators 112. The plurality of regulators 112 are protrusions for forming the plurality of recess-shaped notches 43 described above. The upper mold 120 includes a molding surface 121 for forming a rear surface of the housing 40.

As shown by a thin long-dash, double short-dash line in FIG. 7, at the housing formation step S20, the lead frame 600 is disposed on the molding surface 111 of the lower mold 110. Each of the plurality of regulators 112 is adjacent to one of the plurality of lead terminals 60. Thus, the plurality of lead terminal 60 of the lead frame 600 is positioned by plurality of regulators 112 relative to the molding surface 111.

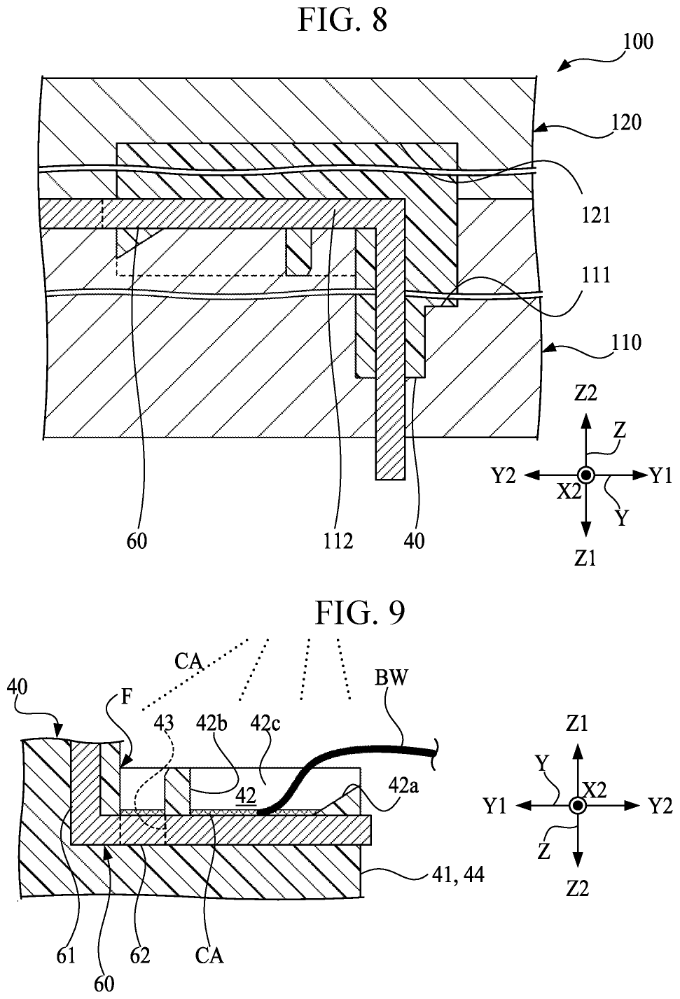

FIG. 8 is a diagram explaining the housing formation step S20. As shown in FIG. 8, at the housing formation step S20, the housing 40 is formed by insert molding in which the mold 100 is used and the lead frame 600 is used as an insert.

Specifically, the lead frame 600 is disposed in the mold 100 as described above, and then the mold 100 is closed, and then the resin composition softened by heating is injected into the mold 100. At this time, movement of the plurality of lead terminals 60 is restricted by the plurality of regulators 112. Thereafter, the resin composition in the mold 100 is cooled until it reaches a temperature less than a softening temperature of the resin composition to cure the resin composition. Thus, the housing 40 is obtained that is integrated with the lead frame 600. Then, the housing 40 is removed from the mold 100.

FIG. 9 is a diagram explaining the wire formation step S30 and the coating step S40. At the wire formation step S30, the plurality of bonding wires BW is formed by wire bonding in which ultrasonic waves are used. At this time, since the first side surface 42a is inclined as described above, it is possible to substantially prevent not only contact between the first side surface 42a and one of the plurality of bonding wires BW, but also contact between the first side surface 42a and a capillary for wire bonding.

At the coating step S40 after the wire formation step S30, the coating material CA for enhancing adhesion of the housing 40 to the encapsulating resin material PA is applied to the inner wall surface F of the housing 40. The coating material CA may be a polyamide-based coating material. A method for applying the coating material CA to the inner wall surface F of the housing 40 is not particularly limited. The method may be a known method such as spraying or dipping.

According to the semiconductor module 10 described above, the housing 40 includes the recess 42 having the bottom surface that is constituted of at least the part of the pad 62 such that the recess 42 surrounds the pad 62. Thus, the pad 62 is pressed against the housing 40. As a result, in a state in which ultrasonic waves are used for wire bonding by which the bonding wire BW is coupled to the lead terminal 60, it is possible to substantially prevent resonance from causing a decrease in coupling strength of the lead terminal 60 to the housing 40. In addition, the first side surface 42a has the first end adjacent to the bottom surface of the recess 42 and the second end closer to the corresponding semiconductor element 21 or 22 than the first end. The first side surface 42a is inclined relative to the direction perpendicular to the pad 62 such that the second end of the first side surface 42a is higher than the first end of the first side surface 42a. Thus, it is possible to reduce contact between the bonding wire BW and the housing 40. In addition, when the encapsulating resin material PA is injected into the housing 40, it is possible to maintain the coating material CA, which enhances adhesion of the housing 40 to the encapsulating resin material PA, in the recess 42. As a result, adhesion of the housing 40 to the encapsulating resin material PA can be improved by the coating material CA. Therefore, it is possible to improve reliability of the semiconductor module 10.

### 2. Modifications

The present disclosure is not limited to the first embodiment described above, and various modifications described below can be made thereto. In addition, the first embodiment and each of the modifications may be combined with others as appropriate.

### 2-1. First Modification

In the first embodiment described above, a configuration is described in which each lead terminal 60 is made of a metallic plate having an L-shape. However, the present disclosure is not limited thereto. The shape of each lead terminal 60 may be freely selected as long as each lead terminal 60 includes the pad 62.

### 2-2. Second Modification

In the first embodiment described above, a configuration is described in which the bottom surface of the recess 42 has a shape of a rectangle in plan view. However, the present disclosure is not limited thereto. In plan view, the bottom surface of the recess 42 may have a shape of a polygon other than a rectangle.

### 2-3. Third Modification

In the first embodiment described above, a configuration is described in which the coating material CA is used. However, the present disclosure is not limited thereto. The coating material CA may be used or may be omitted as appropriate.

### DESCRIPTION OF REFERENCE SIGNS

4 . . . wall, 10 . . . semiconductor module, 21 . . . semiconductor element, 22 . . . semiconductor element, 22a . . . control electrode, 30 . . . circuit board, 31 . . . insulated substrate, 32 . . . circuit plate, 33 . . . heat radiating plate, 40 . . . housing, 41 . . . opening, 41a . . . step surface, 41b . . . partition, 42 . . . recess, 42a . . . first side surface, 42b . . . second side surface, 42c . . . second side surface, 43 . . . recess-shaped notch, 51 . . . terminal, 52 . . . terminal, 53 . . . terminal, 60 . . . lead terminal, 61 . . . pin, 62 . . . pad, 71 . . . wiring board, 72 . . . wiring board, 80 . . . base, 100 . . . mold, 110 . . . lower mold, 111 . . . molding surface, 112 . . . regulator, 120 . . . upper mold, 121 . . . molding surface, 600 . . . lead frame, BW . . . bonding wire, CA . . . coating material, H . . . height, HO . . . height, PA . . . encapsulating resin material, S10 . . . preparation step, S20 . . . housing formation step, S30 . . . wire formation step, S40 . . . coating step, S50 . . . encapsulating step, W . . . distance, θ . . . inclination angle.

What is claimed is:

1. A semiconductor module comprising:
a circuit board provided with a semiconductor element;
a housing for housing the semiconductor element;
a lead terminal penetrating the housing to extend from an inside of the housing to an outside of the housing; and
a bonding wire for electrically connecting the semiconductor element and the lead terminal to each other within the housing,
wherein the lead terminal includes a pad coupled to the bonding wire,
wherein the housing includes a recess having a bottom surface that is constituted of at least a part of the pad such that the recess surrounds the pad,
wherein the recess has a side surface including a first side surface,
wherein the first side surface overlaps with the bonding wire as viewed in a direction of thickness of the circuit board,
wherein the first side surface has a first end adjacent to the bottom surface and a second end closer to the semiconductor element than the first end, and
wherein the first side surface is inclined relative to a direction perpendicular to the pad such that the second end of the first side surface is higher than the first end of the first side surface.

2. The semiconductor module according to claim 1,
wherein the side surface of the recess further includes a second side surface different from the first side surface, and
wherein a height of the first side surface in a direction of depth of the recess is less than a height of the second side surface in the direction of depth of the recess.

3. The semiconductor module according to claim 1,
wherein the lead terminal further includes a portion adjoining the recess, and
wherein the housing further includes two recess-shaped notches between which the portion of the lead terminal adjoining the recess is sandwiched.

4. The semiconductor module according to claim 1,
wherein the housing has a shape of a frame, and
wherein H/W is in a range of 0.5 or more and 2.0 or less, where W is a distance between the first end of the first side surface and an inner peripheral surface of the housing, and H is a height of the first side surface.

5. The semiconductor module according to claim 1, wherein H/L is in a range of 0.2 or more and 0.8 or less, where L is a length of the bottom surface in a direction of expansion of the bonding wire as viewed in the direction of thickness of the circuit board, and H is a height of the first side surface.

6. The semiconductor module according to claim 1, wherein an inclination angle of the first side surface relative to the pad is 45° or less.

7. The semiconductor module according to claim 1, further comprising:
an encapsulating resin material with which the housing is filled; and
a coating material applied to an inner wall surface of the housing, the coating material enhancing adhesion of the housing to the encapsulating resin material.

8. A method for producing a semiconductor module, the semiconductor module including: a circuit board provided with a semiconductor element; a housing for housing the semiconductor element; a lead terminal penetrating the housing to extend from an inside of the housing to an outside of the housing; and a bonding wire for electrically connecting the semiconductor element and the lead terminal to each other within the housing, the method comprising:
preparing a lead frame including the lead terminal;
forming the housing by insert molding in which a mold is used and the lead frame is used as an insert; and
forming the bonding wire,
wherein the lead terminal includes a pad coupled to the bonding wire,
wherein the housing includes a recess having a bottom surface that is constituted of at least a part of the pad such that the recess surrounds the pad,
wherein the recess has a side surface including a first side surface,
wherein the first side surface overlaps with the bonding wire as viewed in a direction of thickness of the circuit board,
wherein the first side surface has a first end adjacent to the bottom surface and a second end closer to the semiconductor element than the first end, and
wherein the first side surface is inclined relative to a direction perpendicular to the pad such that the second end of the first side surface is higher than the first end of the first side surface.
